(19) United States
(12) Patent Application Publication
(10) Pub. No.: US 2010/0283034 A1
(43) Pub. Date: Nov. 11, 2010

(54) Concentration - gradient alloyed semiconductor quantum dots, LED and white light applications

(76) Inventor: Lianhua Qu, Pittsburgh, PA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 11/975,851

(22) Filed: Oct. 22, 2007

Related U.S. Application Data
(60) Provisional application No. 60/853,087, filed on Oct. 20, 2006.

(51) Int. Cl. H01L 33/04; H01L 29/12

(52) U.S. Cl. 257/13; 257/14; 977/774; 257/E33.005; 257/E29.071

(57) ABSTRACT

The present invention involves concentration-gradients alloyed quantum dots that have shell modifications and ligands that lower the barrier for electronic quantum dot activation, and electronic and photonic applications of such quantum dots. The present invention also describes emissive layers using such quantum dots in electronic applications.

This application claims the benefit of priority from U.S. provisional application Ser. No. entitled, Concentration-gradient alloyed semiconductor quantum dots, DED and white light applications, filed Oct. 20, 2007.

### FIELD OF THE INVENTION

This invention pertains to concentration-gradient alloyed semiconductor quantum dots and electronic and photonic applications of the same.

### BACKGROUND OF THE INVENTION

Size-dependant quantum dots, which are spherical semiconductor nanocrystals, are of considerable current interest due to their unique size-dependent properties that are not available from either discrete atoms or bulk solids. See, for example, Alivisatos, J. Plays. Chem. 100: 13226-13239 (1996); Nirmal et al., Acc. Chem. Res. 32: 407-414 (1999); and Eychmiiller, J Phys. Chem. B 32: 104: 6514-6528 (2000). Recent research has demonstrated the wide spectral ranges over which the photoluminescence (PL) of various nanocrystalline materials can be tuned simply by changing the particle size. See, Murray et al., J. Am. Chem. Soc. 115: 8706-8715 (1993); Hines et al., J. Phys. Chem. 100: 468-471 (1996); Micic et al., J. Phys. Chem. 101: 4904-4912 (1997); Harrison et al., J. Mater. Chem. 9:2721-2722 (1999); and Talapin et al., J. Phys. Chem. B 105: 2260-2263 (2001).

The properties of interest for electronic and photonic applications are: high quantum efficiencies, narrow and symmetric emission profiles, wide optical absorption bands, and large molar absorptivities. However, binary semiconductor quantum dots, where the emission wavelength is tuned by changing the particle size from about 1 to 8 nanometers (nm), have a variability of 512 times the volume and 64 times the surface area between the smallest particles and largest particles. These large differences could cause major problems in the dispersion of particles in solvents and polymers, printing and coating applications, photostability, differential brightness and the performance of the quantum dots in LED and fluorescent lighting applications. The larger surface/volume ratio of smaller quantum dots makes them more sensitive to the environment around them and more susceptible to degradation from environmental factors In addition, the surface of the smaller quantum dots have more defects when the growth reaction is stopped quickly to get the right emission wavelength. This introduces defects such as dangling bonds, lattice mismatches and low quantum efficiency. These factors can make the smaller quantum dots significantly less stable (photo, thermal, and chemical) than the larger ones, and consequently reducing lifetime and brightness in device applications.

Korgel et al. overcome some of these problems by generating a series of quantum dots comprising alloys of Zn_{y}CdₗyS and Hg_{y}CdₗyS that, within each series, are fixed in size and composition-tunable. See, Korgel et al., Languir 16: 3588-3594 (2000). Each of the quantum dots has a band gap energy that is linearly related to the molar ratio of the semiconductors comprising the quantum dots. The optical properties of these quantum dots, therefore, are still limited in that the range of emission peak wavelengths of the series of quantum dots is confined to the range of wavelengths defined by the corresponding pure, non-alloyed semiconductor quantum dots, i.e., by the quantum dots consisting of pure HgS, pure CdS, or pure ZnS.

In U.S. Provisional Patent Application Ser. No. 60/468,729, filed on May 7, 2003, Nie et al. describe improved quantum dots comprising an alloy of semiconductors and having unique optical properties that are not limited to the emission peak wavelength range set by the pure, non-alloyed forms of Korgel. Nie describes “concentration-gradient alloyed semiconductor quantum dots” comprising an alloy of a first semiconductor and a second semiconductor, wherein the concentration of the first semiconductor gradually increases from the core of the quantum dot to the surface of the quantum dot and the concentration of the second semiconductor gradually decreases from the core of the quantum dot to the surface of the quantum dot.

The prior art also describes a method of producing a ternary alloyed semiconductor quantum dot comprising an alloy of two semiconductors, AB and AC, wherein A is a species common to the two semiconductors and B and Care each a species found in one of the two semiconductors. The method comprises: (i) providing a first solution under conditions which allow nanocrystal formation to take place; (ii) providing a second solution comprising A, B, and C under conditions which do not allow nanocrystal formation to take place, wherein A is present in the second solution at concentration that is reaction-limiting; (iii) adding the second solution to the first solution, thereby allowing nanocrystal formation to take place; and (iv) changing the conditions to conditions that halt nanocrystal growth and formation.

The prior art further describes a method of producing a series of ternary alloyed semiconductor quantum dots, wherein each quantum dot comprises an alloy of two semiconductors AB and AC, wherein A is a species common to the two semiconductors and B and C are each a species found in one of the two semiconductors. That method comprises: (i) providing a first solution under conditions which allow nanocrystal formation to take place; (ii) providing a second solution comprising A, B, and C at a molar ratio under conditions which do not allow nanocrystal formation to take place, wherein A is present in the second solution at concentration that is reaction-limiting; (iii) adding the second solution to the first solution, thereby allowing nanocrystal formation to take place; (iv) changing the conditions to conditions that halt nanocrystal growth and formation; and (v) repeating steps (i)-(iv) at least one time, thereby producing at least one other quantum dot in the series, wherein each time the molar ratio of A, B, and C is different from the molar ratio of A, B, and C of the other quantum dots of the series.

The prior art also describes a method of producing a ternary concentration-gradient quantum dot comprising a first semiconductor AB and a second semiconductor AC, wherein A is a species common to the first semiconductor and the second semiconductor and B and C are each a species found in only one of the first semiconductor and the second semiconductor. That method comprises: (i) providing a first solution under conditions which allow nanocrystal formation to take place; (ii) providing a second solution comprising A, B, and C at a molar ratio under conditions which do not allow nanocrystal formation to take place, wherein each of B and C are present in the second solution at a concentration that is reaction-limiting; (iii) adding the second solution to the first solution, thereby allowing nanocrystal formation to take place; and (iv) changing the conditions to conditions that halt nanocrystal growth and formation.

The prior art describes a method of producing a series of ternary concentration-gradient quantum dots, wherein each of the quantum dots comprise a first semiconductor AB and a second semiconductor AC, wherein A is a species common to the first semiconductor and the second semiconductor and B and C are each a species found in only one of the first semiconductor and the second semiconductor. The method comprises: (i) providing a first solution under conditions which allow nanocrystal formation to take place; (ii) providing a second solution comprising A, B, and C at a molar ratio under conditions which do not allow nanocrystal formation to take place, wherein each of B and C are present in the second solution at a concentration that is reaction-limiting; (iii) adding the second solution to the first solution, thereby allowing nanocrystal formation to take place; (iv) changing the conditions that allow nanocrystal formation to conditions that halt nanocrystal growth and formation; and (v) repeating steps (i)-(iv) at least one time, thereby producing at least one other quantum dot of the series, wherein each time the molar ratio of A, B, and C is different from the molar ration of A, B, and C of the other quantum dots of the series.

The prior art also describes a series of concentration-gradient quantum dots, wherein: each quantum dot comprises an alloy of a first semiconductor, a second semiconductor and a third semiconductor; for each quantum dot, the concentration of the first semiconductor gradually increases from the core of the quantum dot to the surface of the quantum dot and the concentration of the second semiconductor gradually decreases from the core of the quantum dot to the surface of the quantum dot; the gradient by which the concentration of the first semiconductor increases and the gradient by which the concentration of the second semiconductor decreases from the core of the quantum dot to the surface of the quantum dot varies among the quantum dots of the series; the size of each quantum dot is within about 5% of the size of the average-sized quantum dot; and each quantum dot comprises the same semiconductors.

In U.S. patent application Ser. No. 11/197,620, Qu describes a method of making concentration-gradient alloyed semiconductor quantum dots that contain at least three elements with gradients of these semiconductors from the core of the quantum dot to the surface of the quantum dot. On the surface of these dots (called “cores”), there are two types of shell structures designed to improve quantum efficiency and stability (photo, thermal, and chemical stability). However, unlike the shells described in Qu '620, the shells of the present invention promote charge transfer from on dot to another when fabricated for optical and electrical applications.

In U.S. Provisional Patent Application Ser. No. 60/709,912, Qu describes concentration-gradient alloyed semiconductor quantum dots that contain at least four elements with gradients of these semiconductors from the core of the quantum dot to the surface of the quantum dot. Four-element quantum dots provide the flexibility to design synthetic routes for quantum dots with specific optical and electrical properties to meet the needs for different applications.

In U.S. patent application Ser. No. 11/197,650, Qu describes nanoclusters made by clustering individual quantum dots. These clusters range in size from 20 nm to a few hundred nanometers and contain from 8 to 1,000,000 individual quantum dots. These clusters have significantly increased brightness and stability compared to individual quantum dots. Increased brightness and stability are both potential advantages for optical and electrical applications, such as light emitting diodes (“LED's”), display, white light lighting, photovoltaics, etc.

Although Nie and Qu describe quantum dots having various properties, and modifications to improve the efficiency, stability and solubility of the same, particularly for life science applications, none of the quantum dots described in the prior art, or methods for producing the same, contemplate or consider modifications for their improvement for electronic applications. Further, none of the prior art considers or anticipates modification of the shell of a quantum dot to improve its conductivity, modification of the shell of the quantum dots through surface ligands, or quantum dot properties for electronic applications.

### BRIEF DESCRIPTION OF THE INVENTION

The present invention involves quantum dots that have shell modifications and ligands that lower the barrier for electronic quantum dot activation and electronic and photonic applications of such quantum dots including, but not limited to, their use as the light emitting layer in a light emitting diode (or “LED”), organic light emitting diode (or “OLED”), flat panel display and their use in an infrared emitting diode (or “IRED”). The quantum dots of the present invention can be used as a light emitting phosphor in a fluorescent light bulb or a hybrid incandescent/fluorescent light bulb design. The quantum dots of the present invention can be used as light absorption materials in a photovoltaic cell used for sensitive detection of electromagnetic radiation in radiometry, optical communication, spectroscopy, and other applications, or for power generation system to provide required values of current and/or voltage.

Similarly, the quantum dots of the present invention can be used as photovoltaic materials in a solar cell used as sensitive detection of electromagnetic radiation in radiometry, optical communication, spectroscopy, and other applications, or as electric power generation system to provide required values of current and/or voltage.

### DETAILED DESCRIPTION OF THE INVENTION

The concentration-gradient alloyed quantum dots, and methods for making them, as described in Nie (U.S. Provisional Patent Application Ser. No. 60/468,729) and Qu (U.S. patent application Ser. No. 11/197,620 and U.S. Provisional Patent Application Ser. No. 60/709,912), are well-known in the prior art.

Further, nanoclusters, as described in Qu U.S. patent application Ser. No. 11/197,650, have been used as functional material in optical and electronic applications as the quantum dots do with increased quality, such as higher quantum efficiency and better stability, are known. One of ordinary skill in the art will readily appreciate that the quantum dots of the present invention can be clustered together resulting in improved optical and electronic properties such as quantum efficiency and stability and resistance to photo, thermal and chemical degradation. In addition, nanoclusters overcome the problem of “blinking” with individual quantum dots. Quantum dot emission is not continuous under certain conditions. The clustering of individual quantum dots ensures continuous emission from the particle.

The prior art describes core/shell structure of quantum dots to improve the stability and quantum efficiency and creating a shell with of another semiconductor material with a wider band gap than the core. Despite this method of improving the quality of quantum dots for optical applications, until the present invention, the shell has not been modified in a manner that considers or optimizes electronic applications. In fact, the wider band gap of shell to core described in the prior art may decrease the charge transfer rate for electrons between the core and the shell, and thereby reduces their efficiency for electronic applications.

The present invention provides for shell modifications to ensure appropriate shell-to-core transfer of electrons. The quantum dot shell provided herein is modified to be conductive, semi-conductive, non-conductive, or a combination of these properties, to tailor the shell properties for a particular application. These modifications also provide for improved passivity of the surface of the core. In addition, the shell structure of the present invention results in a better charge transfer rate than conventional shell. For detailed information about the shell structure for quantum dots generally, see U.S. patent application Ser. No. 11/197,620.

The present invention also provides for the surface ligand modification of quantum dots to provide for direct and appropriate electronic charging or pumping of the quantum dot. Ligands are chosen that have at least one group that has a strong association with a surface atom of the quantum dot. These ligands include simple small molecules, longer carbon chain molecules, single functional group molecules, multiple functional group molecules and polymers. The ligands can be non-conductive or conductive depending on the specific electronic application. The ligands also can be volatile.

Further, based on the unique properties of quantum dots and nanoclusters mentioned above, they can be used in lieu of bulk materials when the bulk materials with desired electronic properties are not available. In this instance, the quantum dots are arranged and deposited onto a substrate, e.g., in an array as a thin film, or as layers of thin films, on a support substrate, or as a coating on or around another electronic material. Subsequently, the support substrate and layered quantum dot film or other coated electronic material can be processed as needed in similar fashion to bulk semiconductor materials with the unique properties of the quantum dots now available for use in electronic and optoelectronic devices.

For optical and electronic applications of the quantum dots in the present invention, the quantum dots can be in different phases (solid, liquid, and gas) when used to fabricate a pure quantum dot layer, a quantum dot/organic material composition, a quantum dot/inorganic material composition, a quantum dot/biomaterial composition or a quantum dot/conductive matrix system. An example of a specific quantum dot/conductive matrix system is a composite film having a conductive polymer layer and quantum dot-containing light-emitting layer.

What is claimed is:

1. A concentration-gradient quantum dot comprising an alloy of a first semiconductor and a second semiconductor, wherein the concentration of the first semiconductor gradually increases from the core of the quantum dot to the surface of the quantum dot and the concentration of the second semiconductor gradually decreases from the core of the quantum dot to the surface of the quantum dot, and further comprising a conductive polymer shell.

2. A concentration-gradient quantum dot comprising an alloy of a first semiconductor and a second semiconductor, wherein the concentration of the first semiconductor gradually increases from the core of the quantum dot to the surface of the quantum dot and the concentration of the second semiconductor gradually decreases from said core of the quantum dot to said surface of the quantum dot, and further comprising at least one ligand on said surface of the quantum dot.

3. A concentration-gradient quantum dot of claim 2 wherein said ligand is selected from the group of simple small molecules, carbon chain molecules, single functional group molecules, multiple functional group molecules and polymers.

4. A concentration-gradient quantum dot of claim 3 wherein said ligand is conductive.

5. A concentration-gradient quantum dot of claim 3 wherein said ligand is non-conductive.

6. A concentration-gradient quantum dot of claim 3 wherein said ligand is volatile.

7. A concentration-gradient quantum dot of claim 4 where said ligand is a polymer.

8. A light emitting layer in an electronic device using a plurality of the concentration-gradient quantum dot of claim 1, 4, 6 or 7.

9. A light emitting layer in an electronic device using a plurality of the concentration-gradient quantum dot of claim 1, 4, or 6 wherein said plurality is on the surface of an inorganic solid state layer.

10. A light emitting layer in an electronic device of claim 8 wherein said plurality is embedded in an organic layer.

11. A light emitting layer in an electronic device of claim 8 wherein said plurality is in contact with at least one organic layer.
